(19) United States
(12) Patent Application Publication
(10) Pub. No.: US 2011/0017264 A1
(43) Pub. Date: Jan. 27, 2011

(54) THERMAL MANAGEMENT METHOD AND DEVICE FOR SOLAR CONCENTRATOR SYSTEMS

(75) Inventors: Patrick Weber, Santa Clara, CA (US); Kevin Gibson, Redwood City, CA (US); Ramon Rosal Reglos, San Ramon, CA (US); Rick Briere, Santa Clara, CA (US); Alelie Funcell, Fremont, CA (US)

Correspondence Address: AMPACC Law Group, PLLC, 6100 219th Street SW, Suite 580, Mountlake Terrace, WA, 98043, US

(73) Assignee: Solaria Corporation, Fremont, CA (US)

(21) Appl. No.: 12/389,310

(22) Filed: Feb. 19, 2009

Related U.S. Application Data
(60) Provisional application No. 61/030,553, filed on Feb. 21, 2008.

(51) Int. Cl. H01L 31/052

(52) U.S. Cl. 136/246

(57) ABSTRACT

A photovoltaic device. The photovoltaic device includes a photovoltaic region including a surface region and characterized by a first thermal expansion constant. The surface region includes a first portion and a second portion, the second portion includes a first edge region and a second edge region. The photovoltaic device includes a concentrator element comprising substantially of a polymer material and being characterized by a second thermal expansion constant. The concentrator element includes an aperture region and an exit region. The photovoltaic device includes an elastomer material to couple the first portion of the surface region of the photovoltaic region to the exit region of the concentrator element, while the first edge region and the second edge region remain exposed. The first edge region and the second edge region allow for compensation by at least thermal expansion of the concentrator element for a change in temperature ranging from about −45 Degrees Celsius to about 95 Degrees Celsius to maintain the exit region to be optically coupled to the photovoltaic region.

### CROSS-REFERENCES TO RELATED APPLICATIONS

This application claims priority to and benefit from U.S. Provisional Patent Application No. 61/030,553, filed Feb. 21, 2008 and commonly assigned, the disclosure of which is hereby incorporated herein by reference for all purposes.

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

### BACKGROUND OF THE INVENTION

The present invention relates generally to solar energy techniques. In particular, the present invention provides a method and resulting device fabricated from a plurality of photovoltaic regions provided within one or more substrate members. More particularly, the present invention provides a method and resulting device for manufacturing the photovoltaic regions within the substrate member, which is coupled to a plurality of concentrating elements. Merely by way of example, the invention has been applied to solar panels, commonly termed modules, but it would be recognized that the invention has a much broader range of applicability.

As the population of the world increases, industrial expansion has lead to an equally large consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

Concurrent with oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many characteristics that are very desirable! Solar energy is renewable, clean, abundant, and often widespread. Certain technologies developed often capture solar energy, concentrate it, store it, and convert it into other useful forms of energy.

Solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of silicon bearing wafer materials. Such wafer materials are often costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification, and may be described in more detail below.

From the above, it is seen that techniques for improving solar devices is highly desirable.

### BRIEF SUMMARY OF THE INVENTION

According to the present invention, techniques related to solar energy are provided. In particular, the present invention provides a method and resulting device fabricated from a plurality of photovoltaic regions provided within one or more substrate members. More particularly, the present invention provides a method and resulting device for manufacturing the photovoltaic regions within the substrate member, which is coupled to a plurality of concentrating elements. Merely by way of example, the invention has been applied to solar panels, commonly termed modules, but it would be recognized that the invention has a much broader range of applicability.

In a specific embodiment, a photovoltaic device is provided. The photovoltaic device includes a photovoltaic region. The photovoltaic region includes a surface region and characterized by a first thermal expansion constant. The surface region includes a first portion and a second portion. The second portion includes a first edge region and a second edge region. In a specific embodiment, the photovoltaic device includes a concentrator element which is substantially of a polymer material. The concentrator element includes an aperture region and an exit region. The concentration element is characterized by a second thermal expansion constant. Preferably, the concentrator element is coupled to the exit region of the photovoltaic region. In a specific embodiment, the photovoltaic device includes an elastomer material which couples the first portion of the surface region of the photovoltaic region to the exit region of the concentrator element while the first edge region and the second edge region remain exposed. In a specific embodiment, the first edge region and the second edge region allow for compensation by at least thermal expansion of the concentrator element for a change in temperature ranging from about −45 Degrees Celsius to about 95 Degrees Celsius to maintain the exit region to be optically coupled to the photovoltaic region.

Many benefits are achieved by way of the present invention over conventional techniques. For example, the present technique provides an easy to use process that relies upon conventional technology such as silicon materials, although other materials can also be used. Additionally, the method provides a process that is compatible with conventional process technology without substantial modifications to conventional equipment and processes. Preferably, the invention provides for an improved solar cell, which is less costly and easy to handle. Such solar cell uses a plurality of photovoltaic regions, which are sealed within one or more substrate structures according to a preferred embodiment. In a preferred embodiment, the invention provides a method and completed solar cell structure using a plurality of photovoltaic strips free and clear from a module or panel assembly, which are provided during a later assembly process. Also in a preferred embodiment, one or more of the solar cells have less silicon per area (e.g., 80% or less, 50% or less) than conventional solar cells. In preferred embodiments, the present method and cell structures are also light weight and not detrimental to building structures and the like. That is, the weight is about the same or slightly more than conventional solar cells at a module level according to a specific embodiment. In a preferred embodiment, the present solar cell using the plurality of photovoltaic strips can be used as a “drop in” replacement of conventional solar cell structures. As a drop in replacement, the present solar cell can be used with conventional solar cell technologies for efficient implementation according to a preferred embodiment. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is an expanded view of a solar cell according to an embodiment of the present invention.

FIG. 2 is a more detailed diagram of a solar cell concentrator element according to an embodiment of the present invention.

FIG. 2A-2E are simplified diagrams of solar cell concentrating elements according to an embodiment of the present invention.

FIG. 3 is a simplified diagram of a solar cell element according to an embodiment of the present invention.

FIG. 4 is a simplified top-view diagram of a solar cell element according to an embodiment of the present invention.

FIG. 5 is a simplified cross-sectional view diagram of a solar cell element according to an embodiment of the present invention, and

FIG. 6 is a top view diagram of a plurality of concentrating elements for a solar cell according to an embodiment of the present invention.

### DETAILED DESCRIPTION OF THE INVENTION

According to the present invention, techniques related to solar energy are provided. In particular, the present invention provides a method and resulting device fabricated from a plurality of concentrating elements respectively coupled to a plurality of photovoltaic regions. Merely by way of example, the invention has been applied to solar panels, commonly termed modules, but it would be recognized that the invention has a much broader range of applicability.

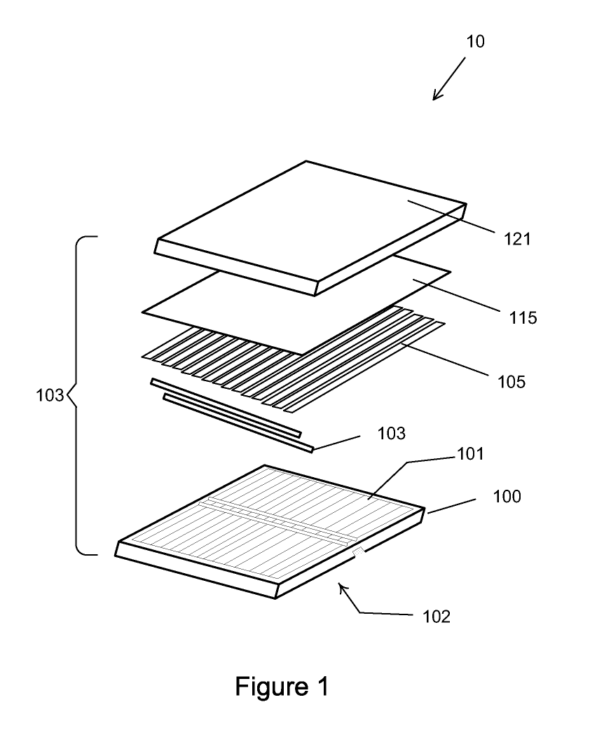

FIG. 1 is a simplified diagram of a solar cell device 10 according to an embodiment of the present invention. This diagram is merely an example, which should not unduly limit the scope of the claims herein. One of ordinary skill in the art would recognize other variations, modifications, and alternatives. As shown is an expanded view of the present solar cell device structure, which includes various elements. The solar cell device has a back cover member 100, which includes a surface area 101 and a back area 102. The back cover member also has a plurality of sites, which are spatially disposed, for electrical members 103, such as bus bars, and a plurality of photovoltaic regions on surface area 101. Alternatively, the surface of the back cover member can be free from any patterns and is merely provided for support and packaging. Of course, there can be other variations, modifications, and alternatives.

In a preferred embodiment, the device has a plurality of photovoltaic strips 105, each of which is disposed overlying the surface area of the back cover member. In a preferred embodiment, the plurality of photovoltaic strips correspond to a cumulative area occupying a total photovoltaic spatial region, which is active and converts sunlight into electrical energy.

An encapsulating material 115 is provided overlying a portion of the back cover member. That is, an encapsulating material forms overlying the plurality of photovoltaic strips, and exposed regions of the surface area, and electrical members. In a preferred embodiment, the encapsulating material can be a single layer, multiple layers, or portions of layers, depending upon the application. In alternative embodiments, as noted, the encapsulating material can be provided overlying a portion of the photovoltaic strips or a surface region of the front cover member, which would be coupled to the plurality of photovoltaic strips. Of course, there can be other variations, modifications, and alternatives.

In a specific embodiment, a front cover member 121 is coupled to the encapsulating material. That is, the front cover member is formed overlying the encapsulate to form a multilayered structure 130 including at least the back cover member, bus bars, plurality of photovoltaic strips, encapsulate, and front cover. In a preferred embodiment, the front cover includes one or more concentrating elements, which concentrate (e.g., intensify per unit area) sunlight onto the plurality of photovoltaic strips. That is, each of the concentrating elements can be associated respectively with each of or at least one of the photovoltaic strips.

Upon assembly of the optional back cover member, bus bars, photovoltaic strips, encapsulate, and front cover, an interface region is provided along at least a peripheral region of the back cover member and the front cover member. The interface region may also be provided surrounding each of the strips or certain groups of the strips depending upon the embodiment. The device has a sealed region and is formed on at least the interface region to form an individual solar cell from the back cover member and the front cover member. The sealed region maintains the active regions, including photovoltaic strips, in a controlled environment free from external effects, such as weather, mechanical handling, environmental conditions, and other influences that may degrade the quality of the solar cell. Additionally, the sealed region and/or sealed member (e.g., two substrates) protect certain optical characteristics associated with the solar cell and also protects and maintains any of the electrical conductive members, such as bus bars, interconnects, and the like. Of course, there can be other benefits achieved using the sealed member structure according to other embodiments.

In a preferred embodiment, the total photovoltaic spatial region occupies a smaller spatial region than the surface area of the back cover. That is, the total photovoltaic spatial region uses less silicon than conventional solar cells for a given solar cell size. In a preferred embodiment, the total photovoltaic spatial region occupies about 80% and less of the surface area of the back cover for the individual solar cell. Depending upon the embodiment, the photovoltaic spatial region may also occupy about 70% and less or 60% and less or preferably 50% and less of the surface area of the back cover or given area of a solar cell. Of course, there can be other percentages that have not been expressly recited according to other embodiments. Here, the terms “back cover member” and “front cover member” are provided for illustrative purposes, and not intended to limit the scope of the claims to a particular configuration relative to a spatial orientation according to a specific embodiment. Further details of each of the various elements in the solar cell can be found throughout the present specification and more particularly below.

In a specific embodiment, the present invention provides a packaged solar cell assembly being capable of stand-alone operation to generate power using the packaged solar cell assembly and/or with other solar cell assemblies. The packaged solar cell assembly includes rigid front cover member having a front cover surface area and a plurality of concentrating elements thereon. Depending upon applications, the rigid front cover member consist of a variety of materials. For example, the rigid front cover is made of polymer material. As another example, the rigid front cover is made of transparent polymer material having a reflective index of about 1.4 or 1.42 or greater. According to an example, the rigid front cover has a Young's Modulus of a suitable range. Each of the concentrating elements has a length extending from a first portion of the front cover surface area to a second portion of the front cover surface area. Each of the concentrating elements has a width provided between the first portion and the second portion. Each of the concentrating elements having a first edge region coupled to a first side of the width and a second edge region provided on a second side of the width. The first edge region and the second edge region extend from the first portion of the front cover surface area to a second portion of the front cover surface area. The plurality of concentrating elements is configured in a parallel manner extending from the first portion to the second portion.

It is to be appreciated that embodiment can have many variations. For example, the embodiment may further includes a first electrode member 103 that is coupled to a first region of each of the plurality of photovoltaic strips and a second electrode 105 member coupled to a second region of each of the plurality of photovoltaic strips.

As another example, the solar cell assembly additionally includes a first electrode member coupled to a first region of each of the plurality of photovoltaic strips and a second electrode member coupled to a second region of each of the plurality of photovoltaic strips. The first electrode includes a first protruding portion extending from a first portion of the sandwiched assembly and the second electrode comprising a second protruding portion extending from a second portion of the sandwiched assembly.

In yet another specific embodiment, the present invention provides a solar cell apparatus. The solar cell apparatus includes a backside substrate member comprising a backside surface region and an inner surface region. Depending upon application, the backside substrate member can be made from various materials. For example, the backside member is characterized by a polymer material.

In yet another embodiment, the present invention provides a solar cell apparatus that includes a backside substrate member. The backside substrate member includes a backside surface region and an inner surface region. The backside substrate member is characterized by a width of about 8 inches and less. For example, the backside substrate member is characterized by a length of about eight inches and less. As an example, the backside substrate member is characterized by a width of about 8 inches and less and a length of more than 8 inches. Of course, there can be other variations, modifications, and alternatives. Further details of the solar cell assembly can be found in U.S. patent application Ser. No. 11/445,933 (Attorney Docket No.: 025902-000210US), commonly assigned, and hereby incorporated by reference herein.

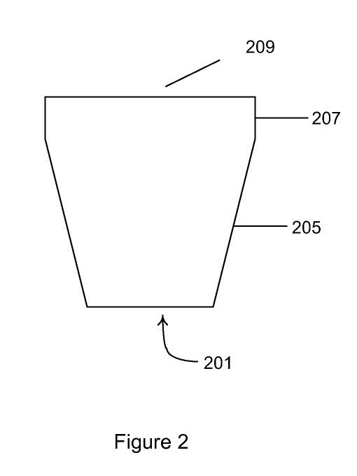

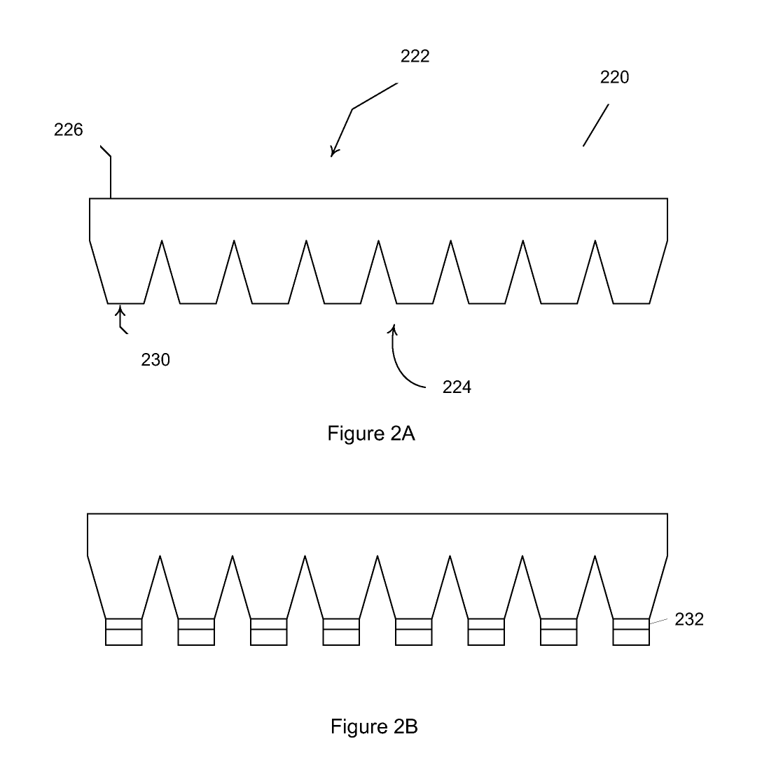

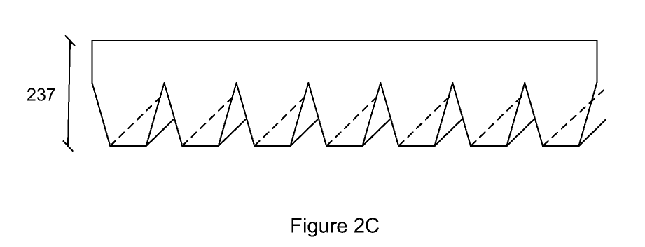

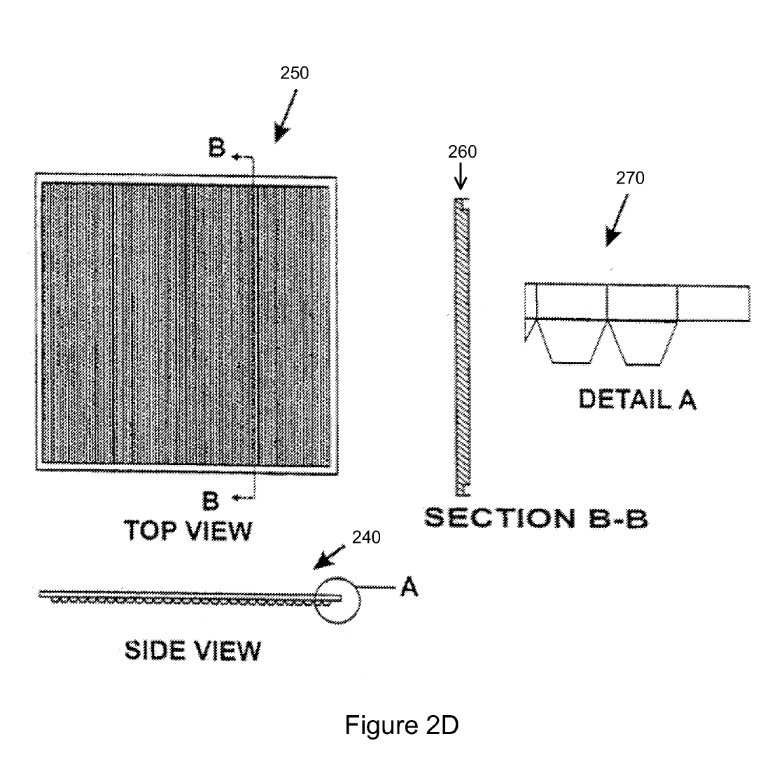

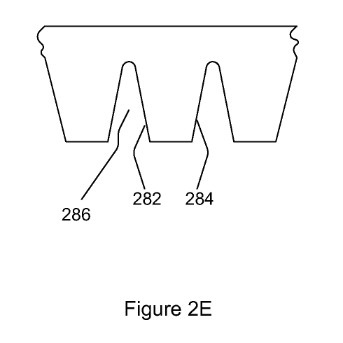

FIG. 2 is a simplified diagram of solar cell concentrating element according to an embodiment of the present invention. This diagram is merely an example, which should not unduly limit the scope of the claims herein. One of ordinary skill in the art would recognize other variations, modifications, and alternatives. As shown, each of the concentrating elements for the strip configuration includes a trapezoidal shaped member. Each of the trapezoidal shaped members has a bottom surface 201 coupled to a pyramidal shaped region 205 coupled to an upper region 207. The upper region is defined by surface 209, which is co-extensive of the front cover. Each of the members is spatially disposed and in parallel to each other according to a specific embodiment. Here, the term “trapezoidal” or “pyramidal” may include embodiments with straight or curved or a combination of straight and curved walls according to embodiments of the present invention. Depending upon the embodiment, the concentrating elements may be on the front cover, integrated into the front cover, and/or be coupled to the front cover according to embodiments of the present invention. Further details of the front cover with concentrating elements is provided more particularly below.

In a specific embodiment, a solar cell apparatus includes a shaped concentrator device 220 operably coupled to each of the plurality of photovoltaic strips 208 as shown in FIG. 2A. The shaped concentrator device has a first side 222 and a second side 224. In addition, the solar cell apparatus includes an aperture region 226 provided on the first side of the shaped concentrator device. As merely an example, the concentrator device includes a first side region and a second side region. Depending upon application, the first side region is characterized by a roughness of about 100 nanometers or 120 nanometers RMS and less, and the second side region is characterized by a roughness of about 100 nanometers or 120 nanometers RMS and less. For example, the roughness is characterized by a dimension value of about 10% of a light wavelength derived from the aperture regions. Depending upon applications, the backside member can have a pyramid-type shape.

As an example, the solar cell apparatus includes an exit region 230 provided on the second side of the shaped concentrator device also shown in FIG. 2A. In addition, the solar cell apparatus includes a geometric concentration characteristic provided by a ratio of the aperture region to the exit region. The ratio can be characterized by a range from about 1.8 to about 4.5. The solar cell apparatus also includes a polymer material characterizing the shaped concentrator device. The solar cell apparatus additionally includes a refractive index of about 1.45 and greater characterizing the polymer material of the shaped concentrator device. Additionally, the solar cell apparatus can include a coupling material 232 formed overlying each of the plurality of photovoltaic strips and coupling each of the plurality of photovoltaic regions to each of the concentrator devices as shown in FIG. 2B. For example, the coupling material is characterized by a suitable Young's Modulus.

As merely an example, the solar cell apparatus includes a refractive index of about 1.45 and greater characterizing the coupling material coupling each of the plurality of photovoltaic regions to each of the concentrator device. Depending upon application, the coupling material is characterized by a thermal expansion constant that is suitable to withstand changes due to thermal expansion of the elements of the solar cell apparatus.

For certain applications, the plurality of concentrating elements has a light entrance area (A1) and a light exit area (A2) such that A2/A1 is 0.8 and less. As shown in FIG. 2C, the light entrance area can include at least a cumulative area of the aperture regions of each of the concentration elements. The light exit area can be a cumulative area of the exit regions of each of the plurality of concentrating elements also shown in FIG. 2C. Each of the exit region is operably coupled to a photovoltaic region in a specific embodiment. As merely an example, the plurality of concentrating elements can have a light entrance area (A1) and a light exit area (A2) such that A2/A1 is 0.8 and less, and the plurality of photovoltaic strips are coupled against the light exit area. In a preferred embodiment, the ratio of A2/A1 is about 0.5 and less. For example, each of the concentrating elements has a height (234) of 7 mm or less. In a specific embodiment, the sealed sandwiched assembly has a width ranging from about 100 millimeters to about 210 millimeters and a length ranging from about 100 millimeters to about 210 millimeters. In a specific embodiment, the sealed sandwiched assembly can even have a length of about 300 millimeters and greater. As another example, each of the concentrating elements has a pair of sides. In a specific embodiment, each of the sides has a surface finish of 100 nanometers or less or 120 nanometers and less RMS. Of course, there can be other variations, modifications, and alternatives.

Referring now to FIG. 2D, the front cover has been illustrated using a side view 240, which is similar to FIG. 2A. The front cover also has a top-view illustration 250. A section view 260 from “B-B” has also been illustrated. A detailed view “A” of at least two of the concentrating elements 270 is also shown. Depending upon the embodiment, there can be other variations, modifications, and alternatives.

Depending upon the embodiment, the concentrating elements are made of a suitable material. The concentrating elements can be made of a polymer, glass, or other optically transparent materials, including any combination of these, and the like. The suitable material is preferably environmentally stable and can withstand environmental temperatures, weather, and other “outdoor” conditions. The concentrating elements can also include portions that are coated with an anti-reflective coating for improved efficiency. Coatings can also be used for improving a durability of the concentrating elements. Of course, there can be other variations, modifications, and alternatives.

In a specific embodiment, the solar cell apparatus includes a first reflective side 282 provided between a first portion of the aperture region and a first portion of the exit region as shown in FIG. 2E. As merely an example, the first reflective side includes a first polished surface of a portion of the polymer material. For certain applications, the first reflective side is characterized by a surface roughness of about 120 nanometers RMS and less.

Moreover, the solar cell apparatus includes a second reflective side 284 provided between a second portion of the aperture region and a second portion of the exit region also shown in FIG. 2E. For example, the second reflective side comprises a second polished surface of a portion of the polymer material. For certain applications, the second reflective side is characterized by a surface roughness of about 120 nanometers and less. As an example, the first reflective side and the second reflective side provide for total internal reflection of one or more photons provided from the aperture region.

In addition, the solar cell apparatus includes a geometric concentration characteristic provided by a ratio of the aperture region to the exit region. The ratio is characterized by a range from about 1.8 to about 4.5. Additionally, the solar cell apparatus includes a polymer material characterizing the shaped concentrator device, which includes the aperture region, exit region, first reflective side, and second reflective side. As an example, the polymer material is capable of being free from damaged caused by ultraviolet radiation.

Furthermore, the solar cell apparatus has a refractive index of about 1.45 and greater characterizing the polymer material of the shaped concentrator device. Moreover, the solar cell apparatus includes a coupling material formed overlying each of the plurality of photovoltaic strips and coupling each of the plurality of photovoltaic regions to each of the concentrator devices. The solar cell apparatus additionally includes one or more pocket regions 286 facing each of the first reflective side and the second reflective side as shown in FIG. 2E. The one or more pocket regions can be characterized by a refractive index of about 1 to cause one or more photons from the aperture region to be reflected toward the exit region. To maximize light entering a photovoltaic strip, the exit region of the subject concentrator element is optically coupled to a photovoltaic strip using a suitable material. Example of such material can include an elastomer material in certain embodiments. Further details of the coupling of the concentrator element to the photovoltaic strip can be found throughout the present specification and more particularly below.

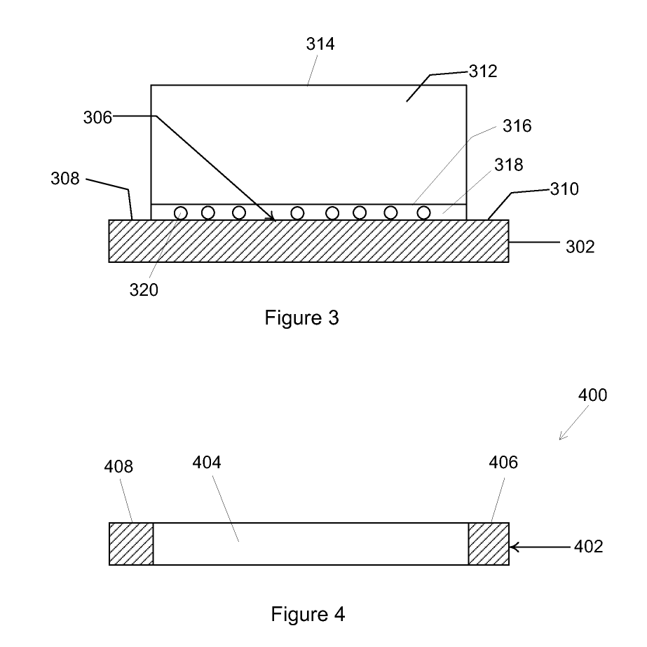

FIG. 3-5 are more detailed diagrams of a solar cell apparatus according to an embodiment of the present invention. These diagrams are merely an examples, which should not unduly limit the scope of the claims herein. One of ordinary skill in the art would recognize other variations, modifications, and alternatives. As shown in FIG. 3, a side view diagram of the solar cell apparatus is provided. The solar cell apparatus includes a photovoltaic region 302 characterized by a first thermal expansivity and includes a surface region 306. Using silicon as the photovoltaic material as an example, the first thermal expansivity can be about 3 ppm to about 4 ppm per Degree Celsius. In a specific embodiment, the solar cell apparatus also includes a solar cell concentrator element 312. The solar cell concentrator element includes an aperture region 314 and an exit region 316. In a specific embodiment, the solar cell concentrator element comprises substantially a polymeric material characterized by a second thermal expansion coefficient. In a specific embodiment, the polymeric material can be an acrylic polymer having a thermal expansivity of about 50 ppm per Degree Celsius or larger. In an alternative embodiment, the polymeric material can be an acrylic polymer having a thermal expansivity of about 70 ppm per Degree Celsius or larger. Preferably, polymeric material can be an acrylic polymer having a thermal expansivity of about 60-80 ppm per Degree Celsius. Of course there can be other variations, modifications, and alternatives.

Also shown in FIG. 3, an elastomer material 318 is provided to optically couple the surface region of the photovoltaic region to the exit region of the solar cell concentrator element. As shown, the photovoltaic region and the solar cell concentrator element are coupled in a first region 307 of the surface region of the photovoltaic region. A second region of the photovoltaic region including a first edge region 308 and a second edge region 310 remain exposed. In a specific embodiment, the exposed first edge region and the exposed second edge region allow for compensation of a difference of thermal expansion of the solar cell concentrator element and the photovoltaic region. In a preferred embodiment, the exposed first edge region and second edge region allow for compensation of a difference in thermal expansion of the solar cell concentrator element and the photovoltaic region in a temperature range from about −45 Degree Celsius to about 95 Degree Celsius and allow for the solar cell concentrator element and the first surface region of the photovoltaic region to remain coupled in the temperature range. Of course there can be other variations, modifications, and alternatives.

Also shown in FIG. 3 and FIG. 4, the elastomer material is provided to optically couple the concentrator element to the photovoltaic region. The elastomer material is preferably a gel like material having a suitable refractive index. Preferably, the elastomer is characterized by an elongation to failure of more than 1,000%. In a specific embodiment, the elastomer material can have a refractive index ranging from about 1.45 to about 1.50 and preferably ranging from 1.46 to about 1.49. In an alternative embodiment, the elastomer material can have a refractive index of greater than 1.49. In a specific embodiment, the elastomer material can be provided as a printable liquid and allowed to cure as the gel like material. The printable liquid can have a viscosity greater than about 2000 centipoise (cps) at room temperature. In a preferred embodiment, the printable liquid can have a viscosity of about 32,000 centipoise at room temperature. The printable liquid is allowed to cure to form the elastomer material. The printable liquid can be cured at a suitable temperature, under ultra violet light or a combination. Alternatively, the printable liquid can be cured at a temperature from about 35 Degree Celsius to about 95 Degree Celsius and preferably from about 40 Degree Celsius to about 50 Degree Celsius. Of course one skilled in the art would recognize other variations, modifications, and alternatives.

In a specific embodiment, a spacer material 320 may be added to the printable liquid. The spacer material provides a uniform spacing between the exit region of the concentrator element and the photovoltaic region. The spacer material may be a transparent material having a suitable refractive index and. In a specific embodiment, the spacer material can be provided as spherical beads having a diameter of about 5 mils and a refractive index of about 1.45 or greater. In a specific embodiment, the spacer material is provided at about 0.2 to about 0.3 weight percent of the printable material. Of course there can be other variations, modifications, and alternatives.

Using again silicon as the photovoltaic material and acrylic as the solar concentrator element material as an example. Each of the concentrator element of the solar concentrator device can have a length of about 150 millimeters. In a specific embodiment, surface region 404 of the photovoltaic region can have a length of 151 mm. First edge region 308 and second edge region 310 of the photovoltaic region can have a width of about 0.5 mm respectively. As noted, the first edge region and the second edge region allow for compensation of a difference in thermal expansivity of the photovoltaic region and the solar concentrator element. Of course there can be other variations, modifications, and alternatives.

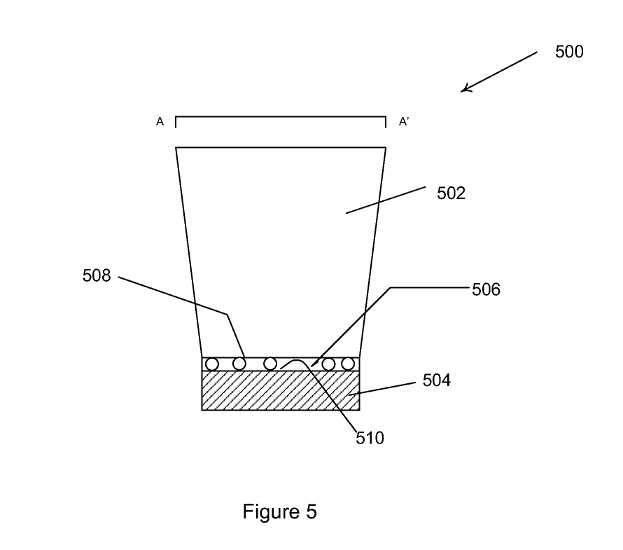

Referring to FIG. 4, the solar cell element is illustrated using a simplified top view diagram 400. The side view B is shown in FIG. 3. As shown in FIG. 4, a photovoltaic region 402 is coupled to exit region of a solar concentrator element 404. First edge region 406 and second edge region 408 are also shown. The solar cell element is also illustrated by way of a simplified cross sectional view A-A′ 500 as shown in FIG. 5. As shown in FIG. 5, the solar cell element includes a concentrator element 502 optically coupled to a photovoltaic region 504 using an elastomer material 506. The elastomer material is provided between an exit region 508 of the concentrator element and an surface region 510 of the photovoltaic region. These diagrams are merely illustrative example and should not unduly limit the claims herein. One skilled in the art would recognize many other variations, modifications, and alternatives.

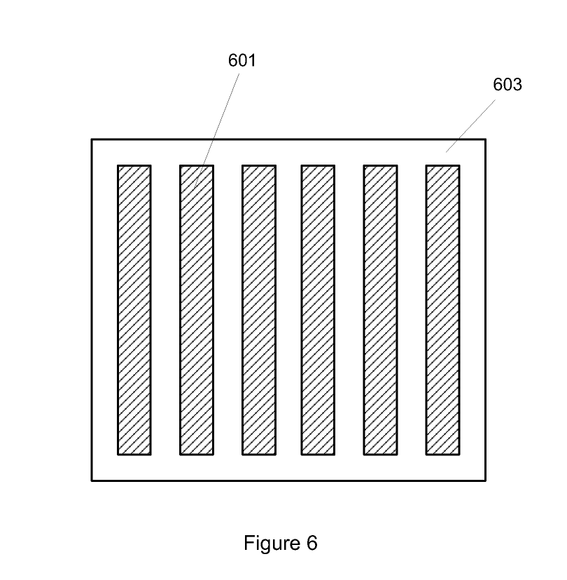

FIG. 6 is a simplified diagram illustrating a top view of a plurality of solar cell elements according to an embodiment of the present invention. As shown, a plurality of photovoltaic strips 601 are provided. Each of the photovoltaic strips has a surface region. The surface region of each of the photovoltaic strips is optically coupled to an exit region of a solar concentrator element. A plurality of the of the solar concentrator elements are connected and essentially provided as a single piece of polymeric material 603. In a specific embodiment, an optically coupling material is provided to couple each of the photovoltaic strips to each of the solar concentrator element. Each of the solar cell elements are spatially disposed and are substantially parallel to each other in a specific embodiment. Of course there can be other variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

1. A photovoltaic device comprising:
a photovoltaic region comprising a surface region and being characterized by a first thermal expansion constant, the surface region including a first portion and a second portion, the second portion including a first edge region and a second edge region;
a concentrator element comprising substantially of a polymer material and being characterized by a second thermal expansion constant, the concentrator element being coupled to the photovoltaic region, the concentrator element including an aperture region and an exit region; and
an elastomer material coupling a first portion of the surface region of the photovoltaic region to the exit region of the concentrator element, while the first edge region and the second edge region remain exposed;
whereupon the first edge region and the second edge region allow for compensation by at least thermal expansion of the concentrator element for a change in temperature ranging from about −45 Degrees Celsius to about 95 Degrees Celsius to maintain the exit region to be optically coupled to the photovoltaic region.

2. The device of claim 1 wherein the polymer material comprises acrylic plastic.

3. The device of claim 1 wherein the photovoltaic region comprises silicon material.

4. (canceled)

5. (canceled)

6. The device of claim 1 wherein the elastomer material is an optical coupling material.

7. The device of claim 1 wherein the aperture region is defined by a length A and the exit region is defined by a length B, where A/B is about 2 and B is about 2 millimeters.

8. The device of claim 1 wherein the exit region has a length of about 150 mm.

9. The device of claim 1 wherein the photovoltaic region has a length of about 150.5 mm.

10. The device of claim 1 wherein the first edge region and the second edge region each has a length of about 0.25 mm.

11. The device of claim 1 wherein the second thermal expansivity is 50 ppm/Degrees Celsius or greater.

12. The device of claim 1 wherein the first thermal expansivity is about 3 ppm/Degrees Celsius.

13. A thermal management method for solar cell device, the method comprising:
providing a photovoltaic region comprising a surface region, the photovoltaic region being characterized by a first thermal expansion constant,
providing a first portion and a second portion on the surface region, the second portion including a first edge region and a second edge region;
providing a concentrator element comprising substantially of a polymer material and being characterized by a second thermal expansion constant, the concentrator element being coupled to the photovoltaic region, the concentrator element including an aperture region and an exit region; and
providing an elastomer material coupling a first portion of the surface region of the photovoltaic region to the exit region of the concentrator element, while the first edge region and the second edge region remain exposed;
whereupon the first edge region and the second edge region allow for compensation by at least thermal expansion of the concentrator element for a change in temperature ranging from about −45 Degrees Celsius to about 95 Degrees Celsius to maintain the exit region to be optically coupled to the photovoltaic region.

14. The method of claim 13 wherein the polymer material comprises acrylic plastic.

15. The method of claim 13 wherein the photovoltaic region comprises silicon material.

16. (canceled)

17. The method of claim 13 wherein the elastomer material is an optical coupling material.

18. The method of claim 13 wherein the aperture region is defined by a width A and the exit region is defined by a width B, where A/B is about 2 and B is about 2 millimeters.

19. The method of claim 13 wherein the exit region has a length of about 150 mm.

20. The method of claim 13 wherein the photovoltaic region has a length of about 150.5 mm.

21. The method of claim 13 wherein the first edge region and the second edge region each has a length of about 0.25 mm.

22. The method of claim 13 wherein the second thermal expansivity is 50 ppm/Degrees Celsius or greater.

23. The method of claim 13 wherein the first thermal expansivity is about 3 ppm/Degrees Celsius.
